(19) United States
(12) Patent Application Publication
(10) Pub. No.: US 2023/0214182 A1
(43) Pub. Date: Jul. 6, 2023

(54) ADDER WITH FIRST AND SECOND ADDER CIRCUITS FOR NON-POWER OF TWO INPUT WIDTH

(71) Applicant: TEXAS INSTRUMENTS INCORPORATED, Dallas, TX (US)

(72) Inventor: Garrett Joseph LIES, Dallas, TX (US)

(21) Appl. No.: 17/566,450

(22) Filed: Dec. 30, 2021

(51) Int. Cl. G06F 7/507; G06F 7/552; H03K 19/20

(52) U.S. Cl. CPC G06F 7/507; G06F 7/552; H03K 19/20

(57) ABSTRACT

A method includes receiving, by an x-bit adder, first and second addends. The x bits comprise a first portion and a second portion, the first portion is a power of two number of bits, and x is not a power of two. The method also includes computing a first sum of the first and second addends corresponding to the first portion. Computing the first sum provides a carry out bit. The method includes computing a non-incremented sum of the first and second addends corresponding to the second portion; computing an incremented sum of the first and second addends corresponding to the second portion; selecting one of the non-incremented sum and the incremented sum, responsive to the carry out bit, as a second sum; and providing a final sum by concatenating the second sum and the first sum.

### SUMMARY

In accordance with at least one example of the disclosure, a method includes receiving, by an x-bit adder, first and second addends. The x bits comprise a first portion and a second portion, the first portion is a power of two number of bits, and x is not a power of two. The method also includes computing a first sum of the first and second addends corresponding to the first portion. Computing the first sum provides a carry out bit. The method includes computing a non-incremented sum of the first and second addends corresponding to the second portion; computing an incremented sum of the first and second addends corresponding to the second portion; selecting one of the non-incremented sum and the incremented sum, responsive to the carry out bit, as a second sum; and providing a final sum by concatenating the second sum and the first sum.

In accordance with another example of the disclosure, a device includes a first adder circuit configured to compute a first sum of a first portion of first and second addends and generate a carry out bit associated with the first sum. The first portion is a power of two number of bits. The device also includes a second adder circuit configured to compute a non-incremented sum of a second portion of the first and second addends; compute an incremented sum of the second portion of the first and second addends; and select one of the non-incremented sum and the incremented sum, responsive to the carry out bit, as a second sum. A final sum of the device comprises the second sum concatenated with the first sum, and the final sum is not a power of two number of bits.

In accordance with yet another example of the disclosure, a device includes a first adder circuit configured to compute a first sum of a first portion of first and second addends and provide a first carry out bit associated with the first sum. The first portion is a power of two number of bits. The device also includes a second adder circuit configured to compute a first non-incremented sum of a second portion of the first and second addends; provide a non-incremented carry out bit associated with the first non-incremented sum; compute a first incremented sum of the second portion of the first and second addends; provide an incremented carry out bit associated with the first incremented sum; and select one of the first non-incremented sum and the first incremented sum, responsive to the first carry out bit, as a second sum. The device further includes a third adder circuit configured to compute a second non-incremented sum of a third portion of the first and second addends; compute a second incremented sum of the third portion of the first and second addends; and select one of the second non-incremented sum and the second incremented sum, responsive to the non-incremented carry out bit, the incremented carry out bit, and the first carry out bit, as a third sum. A final sum of the device comprises the third sum concatenated with the second sum, concatenated with the first sum, and the final sum is not a power of two number of bits.

### BRIEF DESCRIPTION OF THE DRAWINGS

For a detailed description of various examples, reference will now be made to the accompanying drawings in which:

FIG. 1 is a schematic block diagram of an adder including first and second adder circuits in accordance with various examples;

FIG. 2 is a schematic diagram of a tree adder of the adder of FIG. 1 in accordance with various examples;

FIG. 3 is an example circuit diagram of portions of the tree adder of FIG. 2 in accordance with various examples;

FIG. 4 is a schematic diagram of a portion of the tree adder of FIG. 2 including additional delay incurred when addends cross a power of two boundary in accordance with various examples;

FIG. 5 is a schematic diagram of a modified tree adder in accordance with various examples;

FIG. 6 is a schematic diagram of second adder logic and second sum logic of the second adder circuit in FIG. 1 in accordance with various examples;

FIG. 7 is a is a schematic diagram of an adder using a tree adder and multiple carry select adders in a recursive manner in accordance with various examples; and

FIG. 8 is a flow chart of a method in accordance with various examples.

### DETAILED DESCRIPTION

Tree adders are a type of adder used in digital logic. Tree adders are a relatively faster type of adder that improves the computation of carry bits. One type of tree adder is a Sklansky adder, which reduces the amount of time to determine carry bits, such as relative to slower adder types including ripple-carry adders. Other types of tree adders include a Kogge-Stone adder and a Brent-Kung adder. Tree adders generally perform addition using one level of propagate-generate (PG) logic, n levels of group PG logic (e.g., where 2ⁿ is the number of input bits to the tree adder), and one level of sum logic. The particular function of these logic blocks is described below. However, while tree adders are relatively fast for power of two input widths (e.g., where the inputs to the adder (addends) are 2ⁿ bits, n being an integer), the group PG logic introduces an extra level of gate delay for input widths that cross a power of two boundary (e.g., are non-power of two input widths). For example, for an 8-bit input width, the group PG logic of a tree adder includes log₂(8)=3 levels of logic. However, for a 9- to 16-bit input width, the group PG logic of the tree adder includes log₂(16)=4 levels of logic. Accordingly, using a tree adder for input widths that cross a power of two boundary can introduce an additional delay.

It is useful to improve the efficiency and/or performance of addition operations, including where the addends are not a perfect power of two (e.g., cross a power of two boundary). Accordingly, examples of this description provide such improvements with an adder that is configured to receive first and second addends as inputs, and to provide an output that is a sum of the first and second addends. In some examples, the input width of the adder is not a power of two (e.g., the first and/or second addends cross a power of two boundary). The adder includes a first adder circuit, having a first architecture, that is configured to compute a sum of a first portion of the first and second addends. In an example, the first portion is a less-significant, power of two number of bits of the first and second addends. The adder also includes a second adder circuit that is configured to compute an incremented sum and a non-incremented sum of a second portion of the first and second addends. In an example, the second portion is the remaining (e.g., more significant) bits of the first and second addends. For example, the input width of the adder is x=2ⁿ+y, n being an integer. In this example, the first adder circuit computes the sum of the lower 2ⁿ bits of the first and second addends as the first portion, while the second adder circuit computes the sum of the remaining y bits of the first and second addends as the second portion. As described above, x is not a power of two.

As described, the second adder circuit is configured to provide multiple possible outputs (e.g., sums). The second adder circuit uses adder logic that is not dependent on adder logic of the first adder circuit to determine the incremented and non-incremented sums of the second portion of the first and second addends. In some examples, the width of the second portion is sufficiently small that the possible outputs of the second adder circuit (e.g., the incremented and non-incremented sum) are provided more efficiently (e.g., in less time) than if those output bits were computed by extending the first adder circuit to compute the second portion sum. Subsequently, an output (e.g., a carry out bit) from the first adder circuit is used to select one of multiple possible outputs of the second adder circuit. Accordingly, the second adder circuit is a carry select adder. A final output (e.g., sum) of the adder includes the sum provided by the first adder circuit, concatenated with the selected one of the possible outputs of the second adder circuit. In at least some examples, the final output of the adder is provided responsive to the first adder circuit providing its sum, and thus does not incur an additional delay even though the first and/or second addends cross a power of two boundary. These and other examples are described below, with reference made to the accompanying figures.

In the following examples, reference is made at times to various values having specific numbers of bits, for ease of explanation and/or to demonstrate various circuit functionality. However, the scope of this description is not limited to values having such specific numbers of bits unless explicitly stated. Further, in the following examples, reference is made to certain arrangements of logic gates and/or implementations of logical functions. However, such logical functions can be implemented differently in other examples (e.g., using different logic gates and/or combinations of logic gates), and the scope of this description is not limited to specific arrangements of logic gates unless explicitly stated.

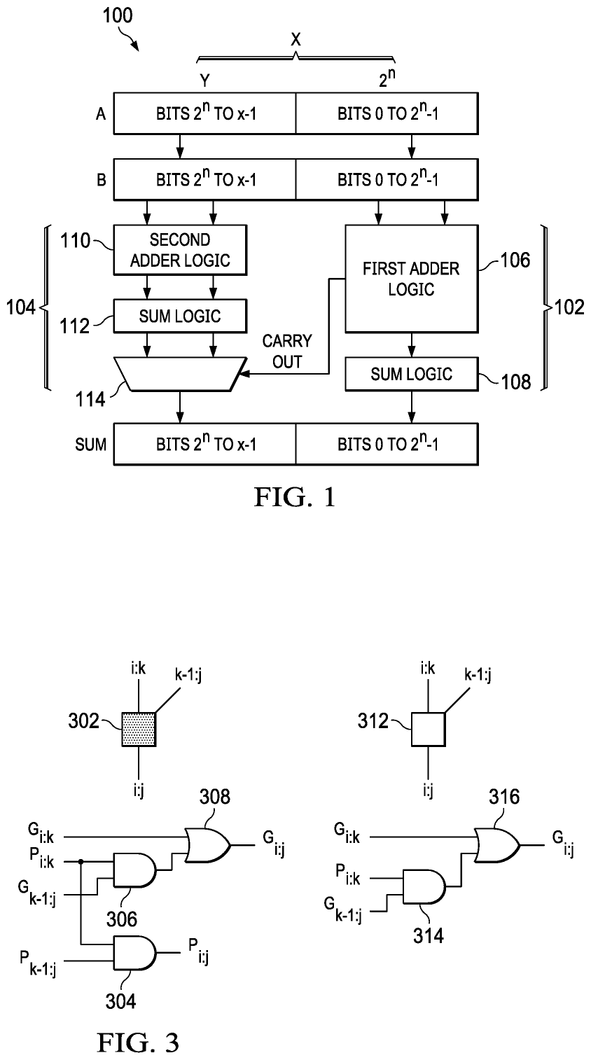

FIG. 1 is a schematic block diagram of an adder 100 in accordance with examples of this description. The adder 100 is configured to receive a first addend (A) and a second addend (B) as inputs. Continuing the above example, the input width of the adder 100 is x=2ⁿ+y, n being an integer. Accordingly, each of the addends A and B are x bits wide, and are shown as including a first or lower (e.g., less-significant) portion that is 2ⁿ bits wide, and a second or upper (e.g., more-significant) portion that is y bits wide. In the examples described herein, x is not a power of two (e.g., the first and/or second addends cross a power of two boundary).

The adder 100 includes a first adder circuit 102 and a second adder circuit 104. In this example, the first adder circuit 102 computes the sum of the lower 2ⁿ bits of the first and second addends, while the second adder circuit 104 computes an incremented and non-incremented sum of the remaining y bits of the first and second addends. The architecture of the first adder circuit 102 is different than the architecture of the second adder circuit 104. For example, the first adder circuit 102 computes the sum of the lower 2ⁿ bits of A and B, while the second adder circuit 104 computes both the incremented and non-incremented sum of the upper y bits of A and B.

In some examples, the first adder circuit 102 includes first adder logic 106 that is implemented as tree adder logic 106 (e.g., the first adder circuit 102 is a tree adder 102), which is a relatively higher performance adder architecture as described above. The tree adder logic 106 performs addition using one level of PG logic and n levels of group PG logic. The tree adder 102 also includes one level of sum logic 108. Although not shown in FIG. 1 for simplicity, the tree adder 102 computes a partial sum of each of the lower 2ⁿ bits by performing an exclusive or (XOR) operation on the input bits for each bit position. For example, a partial sum is computed for bit position 0 by performing A[0]\hat{ }B[0] (e.g., A[0] XOR'd with B[0]), and so on for the other bit positions of the tree adder 102.

The PG logic and group PG logic of the tree adder logic 106 are configured to compute a carry value for each bit position, and the first sum logic 108 is configured to combine the carry value and the partial sum for each bit position to provide a result of the tree adder 102, or the first adder circuit 102. The PG logic and group PG logic of the tree adder logic 106 are described further below. In some examples, the final level of the group PG logic (e.g., the last level prior to the first sum logic 108) is configured to provide a carry out value from the most-significant bit (MSB) position, which in the example of FIG. 1 is bit 2ⁿ−1.

In the example of FIG. 1, the second adder circuit 104 includes second adder logic 110, second sum logic 112, and a multiplexer (mux) 114. The second adder logic 110 and the second sum logic 112 are configured to provide multiple possible outputs (e.g., an incremented sum and a non-incremented sum), unlike the first adder logic 106 and the first sum logic 108, which only provide one output/sum. The incremented sum and the non-incremented sum are provided as inputs to the mux 114. The second adder circuit 104 is thus a carry select adder. As described below, implementing the second adder circuit 104 as a carry select adder enables the possible outputs of the second adder circuit 104 to be provided in less time than if those output bits were computed by extending the first adder logic 106 to the y bits handled by the second adder circuit 104.

The carry out value provided by the group PG logic of the tree adder 102 is provided as a select signal to the mux 114. Accordingly, the mux 114 is configured to provide one of its inputs as an output of the mux 114 responsive to the carry out value provided by the group PG logic of the tree adder 102. A final output (e.g., sum) of the adder 100 includes the sum provided by the first adder circuit 102 (e.g., the output of the first sum logic 108), and the selected one of the possible outputs of the second adder circuit 104. In at least some examples, the sum logic 112 of the second adder circuit 104 provides the multiple possible outputs to the mux 114 at approximately the same time (e.g., with an approximately equal delay) that the first adder logic 106 provides an output to the first sum logic 108. In these examples, the incremented sum and the non-incremented sum are computed concurrently with the sum provided by the first adder circuit 102.

Accordingly, responsive to the carry out being provided by the first adder logic 106, the mux 114 selects one of its inputs to provide as its output (e.g., the sum of the upper y bits of A and B) in parallel with the first sum logic 108 providing the sum of the lower 2ⁿ bits of A and B. Thus, the delay of the adder 100 is based on the n levels of group PG logic in the tree adder logic 106 even though the input width to the adder 100 is greater than 2ⁿ. By contrast, the delay of a conventional tree adder with an input width greater than 2ⁿ would be based on the at least n+1 levels of group PG logic used to compute the sum of an input width greater than 2ⁿ. The adder 100 thus does not incur an additional delay despite A and B crossing a power of two boundary.

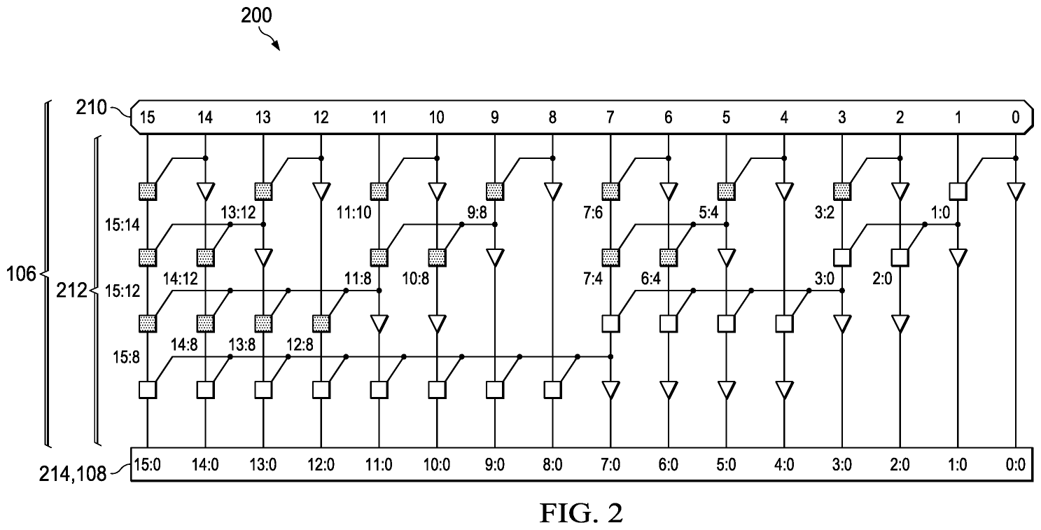

FIG. 2 is a schematic diagram of a tree adder 200 in accordance with examples of this description. In this example, the tree adder 200 has an input width of 16. As described above (although not shown for simplicity), the tree adder 200 computes a partial sum of each of its 2ⁿ input bits by performing an exclusive or (XOR) operation on the input bits for each bit position. For example, a partial sum is computed for bit position 0 by performing A[0]\hat{ }B[0], and so on for the other bit positions of the tree adder 200.

As described above, the tree adder 200 includes one level of PG logic 210, n levels of group PG logic 212, and one level of sum logic 214. The PG logic 210 and group PG logic 212 of the tree adder 200 correspond to the first adder logic 106 of FIG. 1, and are configured to compute a carry value for each bit position. The sum logic 214 corresponds to the first sum logic 108 in FIG. 1, and is configured to combine the carry value and the partial sum for each bit position to provide a result of the tree adder 200.

The PG logic 210 provides the propagate and generate values for each bit position of the tree adder 200. For a particular bit position, PG logic 210 provides an asserted generate signal when, regardless of the carry in value, a carry out will be provided. Accordingly, the generate signal is asserted responsive to both inputs for that bit position (e.g., A[i] and B[i]) being asserted. For a particular bit position, PG logic 210 provides an asserted propagate signal when a carry in for that bit position will propagate to the next bit position. Accordingly, the propagate signal is asserted responsive to one of the inputs for that bit position being asserted and the other input for that bit position being de-asserted (e.g., A[i] is asserted and B[i] is de-asserted, or A[i] is de-asserted and B[i] is asserted). In some examples, for a particular bit position, PG logic 210 provides an asserted kill signal when a carry out will not be produced regardless of the carry in value. Accordingly, the kill signal is asserted responsive to both inputs for that bit position (e.g., A[i] and B[i]) being de-asserted.

The PG logic 210 can provide the generate signal as the output of an AND gate that receives the two input bits for that bit position as its input (e.g., A[i] && B[i]). The PG logic 210 can provide the propagate signal as the output of an XOR gate that receives the two input bits for that bit position as its input (e.g., A[i]\hat{ }B[i]). The PG logic 210 can also provide the propagate signal as the output of an OR gate (e.g., A[i]∥B[i]), because the propagate signal has no effect on the output when the corresponding generate signal is high. The PG logic 210 can provide the kill signal as the output of a NOR gate that receives the two input bits for that bit position as its input (e.g., ˜(A[i]∥B[i])). In some examples, inverted generate and/or propagate signals can be used in the PG logic 210 because NAND and NOR gates are often faster than AND and OR gates.

The group PG logic 212 can be implemented using different architecture depending on the particular tree adder structure being implemented. In one example, the group PG logic 212 is implemented using a Sklansky adder architecture, although in other examples, different types of adder 200 architectures can be used. Irrespective of the particular architecture of the group PG logic 212, each level in the group PG logic 212 is configured to receive the propagate and generate values from either the PG logic 210 (e.g., the first level of group PG logic 212 receives propagate and generate values from the PG logic 210) or from a previous level of the group PG logic 212. For example, the second level of group PG logic 212 receives propagate and generate signals from the first level of group PG logic 212. The group PG logic 212 provides the carry out signal for each bit position of the tree adder 200. The implementation of the group PG logic 212 is described further below, with reference to FIG. 3.

The sum logic 214 receives the carry out signals for each bit position of the tree adder 200 from the group PG logic 212. The sum logic 214 also receives the partial sum (e.g., A\hat{ }B) described above. The sum logic 214 is configured to compute the final sum for the tree adder 200 by XORing the partial sum with the corresponding carry out signals provided by the group PG logic 212 for each bit position. For example, sum logic 214 is configured to XOR the carry out for bit 0 with the partial sum for bit 1, to XOR the carry out for bit 1 with the partial sum for bit 2, and so on. In some examples, the sum logic 214 is configured to pass through the partial sum for bit 0, because there is no carry in to bit position 0.

FIG. 3 are example circuit diagrams of the “shaded cells” 302 and “unshaded cells” 312 that are used to implement the group PG logic 212, shown in FIG. 2. Both the shaded cell 302 and the unshaded cell 312 are configured to receive propagate (P) and generate (G) signals from a previous level. As described above, the first level of group PG logic 212 receives P and G signals from the PG logic 210, and subsequent levels of group PG logic 212 receive P and G signals from preceding levels of group PG logic 212.

In FIG. 3, the cells 302, 312 are described as non-inverting for simplicity. However, in other examples, the successive levels of group PG logic 212 are implemented using alternating, complementary logic (e.g., alternating OAI21 and AOI21 compound gates), such as to reduce delays that would be caused by using inverters that are not necessary. For example, a first level of group PG logic 212 produces an inverted result. However, rather than introduce an inverter to “correct” the inverted result, a second, subsequent level of group PG logic 212 is designed to accept the inverted result and to provide a non-inverted result, which avoids the delay that would be introduced by correcting the result of the first level of group PG logic 212 with an inverter. In one example, the triangle cells in FIG. 2 represent buffers (e.g., to reduce fanout at each logic level. However, in other examples, some or all of the buffers can be replaced with inverters (e.g., to correct for an inverting structure of the group PG logic 212 as needed), or removed from the group PG logic 212.

The colon (:) notation used in FIGS. 2 and 3 indicates a range of bits represented by a particular input to, or output from, the shaded cells 302 and the unshaded cells 312. Both the shaded cell 302 and the unshaded cell 312 are configured to receive P_{i:k}, G_{i:k}, P_{k-1:j}, and G_{k-1:j}. Responsive to receiving such inputs, the shaded cell 302 is configured to provide P_{i:j} and G_{i:j}, and the unshaded cell 312 is configured to provide G_{i:j}. The output of the unshaded cells 312 (G_{i:j}) corresponds to the final carry out for that bit position, but can also act as the carry in to a subsequent (e.g., numerically higher) bit position.

For example, the upper-leftmost shaded cell 302 in FIG. 2 is configured to receive P_{15:15} and G_{15:15} from the PG logic 210 for bit 15, and is also configured to receive P_{14:14} and G_{14:14} from the PG logic 210 for bit 14. The upper-leftmost shaded cell 302 in FIG. 2 is configured to provide P_{15:14} and G_{15:14} as its outputs. Referring again to FIG. 3 and continuing the upper-leftmost example of FIG. 2, the shaded cell 302 includes a first AND gate 304 that is configured to receive P_{15:15} and P_{14:14} as its inputs, and to provide P_{15:14} as its output (e.g., P_{15:14}=P_{15:15} && P_{14:14}). The shaded cell 302 includes a second AND gate 306 that is configured to receive P_{15:15} and G_{14:14} as its inputs, and to provide an intermediate output that is equal to P_{15:15} && G_{14:14}. The shaded cell 302 also includes an OR gate 308 that is configured to receive the intermediate output from the second AND gate 306 and G_{15:15} as its inputs, and to provide G_{15:14} as its output (e.g., G_{15:14}=G_{15:15}∥(P_{15:15} && G_{14:14})).

As another example, the upper-rightmost unshaded cell 312 in FIG. 2 is configured to receive P_{1:1} and G_{1:1} from the PG logic 210 for bit 1, and is also configured to receive P_{0:0} and G_{0:0} from the PG logic 210 for bit 0. The upper-rightmost unshaded cell 312 in FIG. 2 is configured to provide G_{1:0} as its output. Because the upper-rightmost unshaded cell 312 is in bit position 1, G_{1:0} represents the final carry out for that bit position because it represents the full range of bits (e.g., 0 to 1) that can influence the carry result for bit position 1. Similarly, the lower-leftmost unshaded cell 312 in FIG. 2 provides G_{15:0} as its output, and thus represents the final carry out for that bit position 15 as well.

Referring again to FIG. 3 and continuing the upper-rightmost example of FIG. 2, the unshaded cell 312 includes an AND gate 314 that is configured to receive P_{1:1} and G_{0:0} as its inputs, and to provide an intermediate output that is equal to P_{1:1} && G_{0:0}. The unshaded cell 312 also includes an OR gate 316 that is configured to receive the intermediate output from the AND gate 314 and G_{1:1} as its inputs, and to provide G_{1:0} as its output (e.g., G_{1:0}=G_{1:1}∥(P_{1:1} && G_{0:0})).

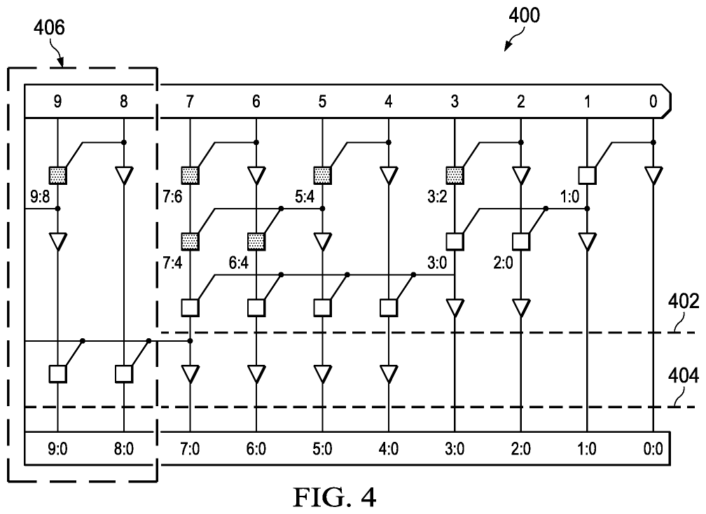

FIG. 4 is a schematic diagram of a portion of the tree adder 200 of FIG. 2, labeled 400 for simplicity, that illustrates the additional delay incurred by a tree adder structure when its inputs (e.g., addends A and B) cross a power of two boundary. The tree adder 400 is configured to receive an input width of 10 bits. If the tree adder 400 only received an input width of 8 bits (e.g., a power of 2), the group PG logic of the tree adder 400 would complete at time 402 (e.g., 3 levels of group PG logic). However, because the tree adder 400 receives inputs that cross the power of two boundary, an additional level of group PG logic is used, which instead completes at time 404 (e.g., 4 levels of group PG logic).

The area 406 of the tree adder 400 corresponds to the input bits that cross the power of two boundary (e.g., bits 8 and 9). In the area 406, the logic of the tree adder 400 is relatively sparse, and these two MSBs wait multiple gate delays for the carry out from bit 7 to be produced (e.g., by the unshaded cell 312 in the bit 7 column). Only after the carry out from bit 7 is produced can the unshaded cells 312 for bits 8 and 9 be computed, which leads to the additional delay described above, in which 4 levels of group PG logic are used.

Accordingly, as described above, the adder 100 reduces the delay compared to the tree adder 400 where the input width crosses a power of two. In particular, referring to the examples of FIG. 4 and the adder 100 of FIG. 1, the first adder circuit 102 is configured to compute the sum of the lower 2ⁿ=8 bits of the addends A and B. The second adder circuit 104, being implemented as a carry select adder, is configured to compute multiple possible outputs (e.g., incremented and non-incremented sums) of the upper y=2 bits of the addends A and B. As described below, the architecture and input width of the second adder circuit 104 enables the multiple possible outputs from the second adder logic 110 and second sum logic 112 to be provided to the mux 114 at approximately the time a carry out from the first adder logic 106 is available (e.g., the final carry out from bit 7).

Accordingly, responsive to the carry out being provided by the first adder logic 106, the mux 114 selects one of its inputs to provide as its output. The output of the mux 114 is the sum of the upper y=2 bits of A and B, and is provided at approximately the same time as the sum logic 106 providing the sum of the lower 2ⁿ=8 bits of A and B. Thus, the delay of the adder 100 is based on the 3 levels of group PG logic in the first adder logic 106, even though the input width to the adder 100 is 10 bits. By contrast, the delay of the tree adder 400 with an input width of 10 bits is based on the 4 levels of group PG logic described above. The adder 100 thus does not incur an additional delay despite A and B crossing a power of two boundary.

As described, the second adder circuit 104 can be implemented as a carry select adder 104 for the upper y bits (continuing the example of FIG. 4, y=2). The carry select adder 104 is configured to provide at least two possible outputs: an incremented output, which assumes that the output from the first adder circuit 102 (e.g., the carry out from the MSB of the first adder logic 106) is a ‘1’; and a non-incremented output, which assumes that the output from the first adder circuit 102 (e.g., the carry out from the MSB of the first adder logic 106) is a ‘0’.

Accordingly, rather than waiting for the carry out from bit 7 to then compute the carry outs for bits 8 and 9, and finally compute the sum, the second adder logic 110 and the second sum logic 112 pre-compute both an incremented output and a non-incremented output. The mux 114 then selects one of the pre-computed outputs provided by the sum logic 112 responsive to the carry out from the MSB of the tree adder 102 (e.g., the carry out from bit 7). In some examples, the 2:1 mux 114 has a delay approximately equal to the first sum logic 108 used by the tree adder 102, and thus the mux 114 provides its output (e.g., the sum of the upper y=2 bits of A and B) at approximately the same time as the first sum logic 108 providing the sum of the lower 2ⁿ=8 bits of A and B, which avoids the additional level of group PG logic present in the area 406 in FIG. 4.

In some examples, the second adder logic 110 is implemented using a similar structure as the first adder logic 106. The second adder logic 110 is at least partially duplicated, however, to provide outputs (e.g., carry out bits) for both the incremented sum and the non-incremented sum that the second sum logic 112 is configured to compute. For example, the second adder logic 110 can be implemented as a Sklansky adder structure, such as that described with respect to FIG. 4, for y=2 bits in the 10-bit example described above. However, because the second adder circuit 104 computes both incremented and non-incremented sums, the second adder logic 110 also includes a duplicate adder structure. In some examples, the duplicate adder structure is a complete duplicate (e.g., the second adder logic 110 includes two Sklansky adder structures), while in other examples, a modified structure can be used that factors out common terms between incremented and non-incremented sums, such as to reuse logic and reduce area requirements.

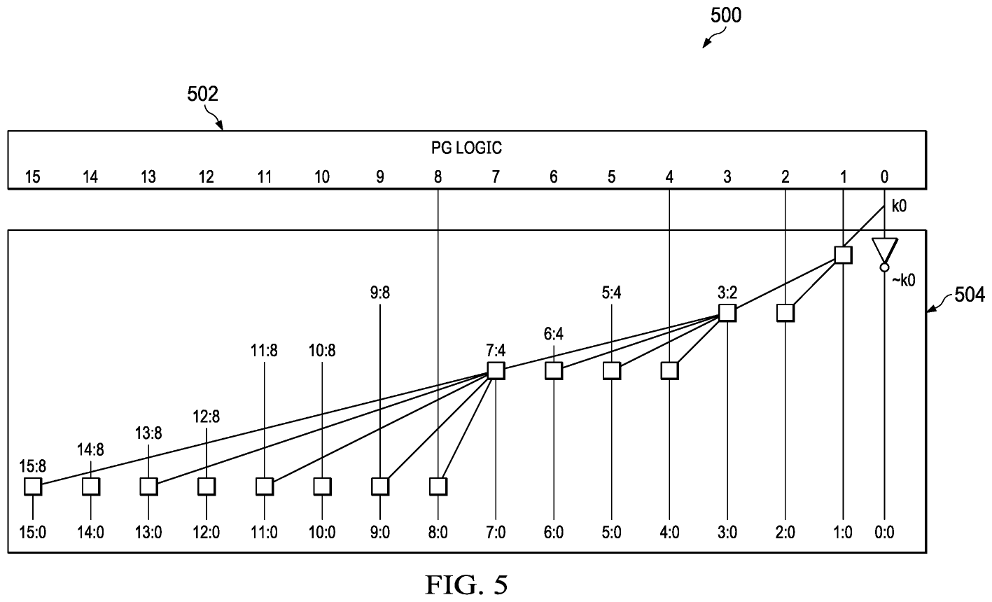

FIG. 5 is a schematic diagram of a modified tree adder 500 in accordance with examples of this description. In this example, the modified tree adder 500 has an input width of 16, corresponding to the example tree adder 200 of FIG. 2, described above. Although y=2 in the 10-bit example described above, FIG. 5 is provided to demonstrate how certain logic from the tree adder 200 can be reused in the second adder logic 110 to compute the carry out bits for both an incremented sum and a non-incremented sum.

For example, the second adder logic 110 uses a tree adder, such as tree adder 200 to compute the carry out bits for a non-incremented result. The second adder logic 110 also uses a modified tree adder 500 to compute the carry out bits for an incremented result. The modified tree adder 500 includes additional unshaded cells 312, but reuses signals from the tree adder 200 that computes the carry out bits for the non-incremented result. Thus, the modified tree adder 500 is dependent on the tree adder 200 of the second adder logic 110 in some examples. For example, 7:4 is provided by the shaded cell 302 in the bit 7 column of the tree adder 200. In FIG. 5, 7:4 also represents the input to the unshaded cell 312 in the bit 7 column, and thus the 7:4 output from the shaded cell 302 in the tree adder can be reused by the modified tree adder 500 (e.g., in addition to being used by the actual subsequent unshaded cell 312 in the bit 7 column of the tree adder 200). As another example, 9:8 is provided by the shaded cell 302 in the bit 9 column of the tree adder 200, and is reused by the unshaded cell 312 in the bit 9 column of the tree adder 500 (e.g., to produce the 9:0 output in FIG. 5), in addition to being used by the actual subsequent unshaded cell 312 in the bit 9 column of the tree adder 200 to produce the 9:0 output in FIG. 2.

The modified tree adder 500 thus reduces the area of logic used to provide the carry out bits for the incremented result (e.g., relative to using a full tree adder 200 to provide the carry out bits for each of the non-incremented result and the incremented result). The modified tree adder 500 includes PG logic 502 and group PG logic 504. The modified tree adder 500 differs from the tree adder 200 in that a different value is used from the PG logic 502 from bit position 0. The tree adder 200 (e.g., for the non-incremented sum) provides the 0:0 output equal to G0 (e.g., the generate signal from bit position 0 of the PG logic 210). This is because the carry in to bit position 0 is assumed to be zero, and thus a carry out for bit position 0 is responsive to the input bits at bit position 0 generating a carry (e.g., the generate signal G0).

However, the modified tree adder 500 is used for the incremented result, as described above. For an incremented sum, the expression for the output 0:0 is G0∥(P0 && Cin), because bit position 0 provides a carry out responsive to a carry in (e.g., Cin) and the input bits at bit position 0 propagating (e.g., the propagate signal P0). In this example, Cin is implied to be a value of one because the incremented result assumes a carry out from the first adder logic 106. Accordingly, the expression for the output 0:0 for the modified tree adder 500 becomes G0∥P0, which can be simplified to P0, because P0 is always asserted if G0 is asserted. P0 is the propagate signal provided by the PG logic 502 for bit position 0. In the example of FIG. 5, the inverted value of P0 (e.g., the kill signal K0) is provided by the PG logic 502, which is then inverted and provided as the 0:0 output. The remainder of the modified tree adder 500 is similar to the unshaded cells 312 of the tree adder 200, except that the carry out from bit position 0 is determined as described above, which assumes that the carry in from the first adder logic 106 is asserted.

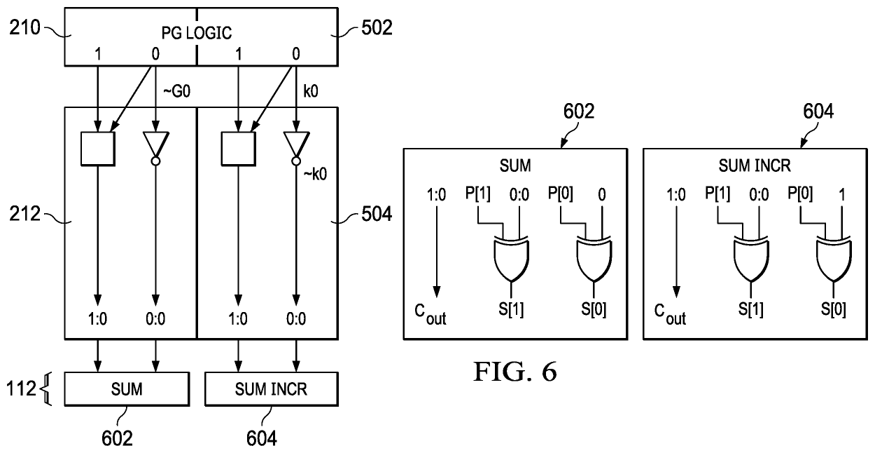

FIG. 6 is a schematic diagram of the second adder logic 110 and the sum logic 112 in the example where y=2, such as the 10-bit addition example described above. PG logic 210 and group PG logic 212 are useful to provide carry out bits for the non-incremented result, while PG logic 502 and group PG logic 504 are useful to provide carry out bits for the incremented result. In this particular example where y=2, the group PG logic 212 and the group PG logic 504 appear similar, except for using different carry out values from bit position 0 as described above. However, extending FIG. 6 to y>2, the PG logic 212 would be configured as in FIG. 2, while the PG logic 504 would be configured as in FIG. 5, and reuse outputs from the PG logic 212 as described above.

Returning to the example of FIG. 6, the sum logic 112 includes non-incrementing sum logic 602 and incrementing sum logic 604. The non-incrementing sum logic 602 is configured to receive the partial sum for bits 1 and 0 (e.g., P[1] and P[0]) and to provide a sum for bits 1 and 0 (e.g., S[1] and S[0]) that is equal to the carry in for that bit position XORed with the partial sum for that bit position. The non-incrementing sum logic 602 provides the non-incremented result, and thus the carry in to bit position 0 is 0, while the carry in to bit position 1 is the output 0:0 from the group PG logic 212 (e.g., the carry out from bit position 0). The non-incrementing sum logic 602 provides the output 1:0 from the group PG logic 212 (e.g., the carry out from bit position 1) as a carry out value Cout.

The incrementing sum logic 604 is configured to receive the partial sum for bits 1 and 0 (e.g., P[1] and P[0]) and to provide a sum for bits 1 and 0 (e.g., S[1] and S[0]) that is equal to the carry in for that bit position XORed with the partial sum for that bit position. The incrementing sum logic 604 provides the incremented result, and thus the carry in to bit position 0 is 1, while the carry in to bit position 1 is the output 0:0 from the group PG logic 504 (e.g., the carry out from bit position 0). The incrementing sum logic 604 provides the output 1:0 from the group PG logic 504 (e.g., the carry out from bit position 1) as a carry out value Cout.

The output of the non-incrementing sum logic 602 is provided as an input to the mux 114, which is selected responsive to the carry out from the first adder logic 106 being a 0. The output of the incrementing sum logic 604 is provided as another input to the mux 114, which is selected responsive to the carry out from the first adder logic 106 being a 1.

Referring to the 10-bit addition example, in which y=2, the second adder circuit 104 thus includes one level of PG logic 210, 502; one level of group PG logic 212, 504; and one level of sum logic 112 prior to the mux 114. In this example, the first adder circuit 102 includes one level of PG logic 210 and three levels of group PG logic 212 before the carry out is provided (e.g., from bit position 7 in the last level of group PG logic 212). Accordingly, the inputs are available to the mux 114 at least by the time that the first adder logic 106 provides the carry out, and thus the second adder circuit 104 provides its output at approximately the same time as the first sum logic 108 provides the output of the first adder circuit 102. As described above, the adder 100 thus does not incur an additional delay despite A and B crossing a power of two boundary.

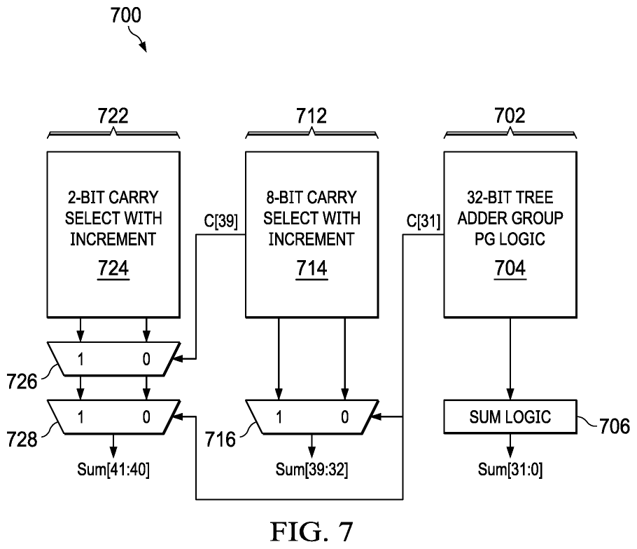

FIG. 7 is a schematic diagram of a circuit 700 that implements the adder 100 architecture described above in a recursive manner, such as to obtain additional width for an adder that crosses a power of two boundary, without incurring an additional delay. In the 10-bit example described above, the second adder circuit 104 sum logic 112 provides both the sum (e.g., by the non-incrementing sum logic 602) and the incremented sum (e.g., by the incrementing sum logic 604) at least by the time that the first adder logic 106 provides the carry out from bit position 7. Accordingly, the mux 114 provides the selected output at approximately the same time as the sum logic 108 for the first sum logic 108.

The circuit 700 extends this concept to include a first adder circuit 702, a second adder circuit 712, and a third adder circuit 722. In this example, the first adder circuit 702 includes 32-bit tree adder group PG logic 704 (e.g., similar to the group PG logic 212 of FIG. 2, extended to a 32-bit width) and 32-bit sum logic 706 (e.g., similar to the sum logic 214 of FIG. 2, extended to a 32-bit width).

The second adder circuit 712 includes an 8-bit carry select adder 714, which is similar to circuits 212, 504, 602, and 604 of FIG. 6, extended to an 8-bit width. Accordingly, the 8-bit carry select adder 714 is configured to compute multiple possible outputs (e.g., incremented and non-incremented sums), which are provided to a mux 716. A carry out from the MSB of the 32-bit tree adder group PG logic 704 (e.g., C[31]) is provided as a select signal to the mux 716. As described above, the 8-bit carry select adder 714 provides its outputs at least by the time that C[31] is provided by the 32-bit tree adder group PG logic 704. The output of the mux 716 is thus the selected one of the incremented sum and the non-incremented sum provided by the 8-bit carry select adder 714.

The third adder circuit 722 includes a 2-bit carry select adder 724, which is similar to circuits 212, 504, 602, and 604 of FIG. 6. Accordingly, the 2-bit carry select adder 724 is configured to compute multiple possible outputs (e.g., incremented and non-incremented sums), which are provided to a first level mux 726. The first level mux 726 is illustrated as a single mux for simplicity. However, the first level mux 726 represents two 2:1 muxes, one to provide an output based on an incremented carry out value (e.g., Ci) and one to provide an output responsive to a non-incremented carry out value (e.g., Cn). Both the incremented and non-incremented carry outs from the MSB of the 8-bit carry select adder 714 (e.g., Ci[39] and Cn[39]) are provided as select signals to the first level mux 726. As described above, the 2-bit carry select adder 724 provides its outputs at least by the time that Ci[39] and Cn[39] are provided by the 8-bit tree adder group PG logic 704. A first output of the first level mux 726 is thus a selected one of the incremented sum and the non-incremented sum provided by the 2-bit carry select adder 724 responsive to the incremented carry out from the MSB of the 8-bit carry select adder 714 (e.g., Ci[39]). A second output of the first level mux 726 is thus a selected one of the incremented sum and the non-incremented sum provided by the 2-bit carry select adder 724 responsive to the non-incremented carry out from the MSB of the 8-bit carry select adder 714 (e.g., Cn[39]).

The first and second outputs of the first level mux 726 are provided to a second level mux 728. The carry out from the MSB of the 32-bit tree adder group PG logic 704 (e.g., C[31]) is provided as a select signal to the second level mux 728. As above, the first level mux 726 is configured to provide its outputs at least by the time that C[31] is provided by the 32-bit tree adder group PG logic 704. The output of the second level mux 728 is thus the final sum selected by the carry out of the first adder circuit 702.

The functionality of the circuit 700 is further illustrated by the following example. As described, a tree adder (e.g., first adder circuit 702) performs addition on bits 31:0, a first carry select adder (e.g., second adder circuit 712) performs addition on bits 39:32, and a second carry select adder (e.g., third adder circuit 722) performs addition on bits 41:40. The following expression demonstrates how to select bits 41:40 using the carry outs provided by the 8-bit carry select adder 714. In these expressions, S is the final sum output for a particular bit position, C is the carry out for a particular bit position, Si is the incremented sum for a particular bit position, and Sn is the non-incremented sum for a particular bit position. Accordingly, the final sum for bit 40 can be expressed:

S[40]=C[39] && Si[40]∥˜C[39] && Sn[40]

S[40] can thus be selected responsive to C[39] from the 8-bit carry select adder 714. However, as explained above, C[39] is not determined until its value has been selected by C[31] from the 32-bit tree adder 704. Accordingly, C[39] is expressed as being dependent on the value of C[31], in which Ci is the incremented carry value for a particular bit position, and Cn is the non-incremented carry value for a particular bit position:

C[39]=C[31] && Ci[39]∥˜C[31] && Cn[39]

This expression for C[39] is substituted in the equation for S[40] to provide the following expression:

S[40]=(C[31] && Ci[39]∥˜C[31] && Cn[39]) && Si[40]∥˜(C[31] && Ci[39]∥˜C[31] && Cn[39]) && Sn[40]

Distributing terms and applying DeMorgan's theorem provides the following expression:

S[40]=(C[31] && Ci[39] && Si[40])∥(˜C[31] && Cn[39] && Si[40])∥((˜C[31]∥˜Ci[39]) && (C[31]∥˜Cn[39])) && Sn[40]

Expanding terms further, provides the following expression:

S[40]=(C[31] && Ci[39] && Si[40])∥(˜C[31] && Cn[39] && Si[40])∥(˜C[31] && C[31] && Sn[40])∥(˜C[31] && ˜Cn[39] && Sn[40])∥(˜Ci[39] && C[31] && Sn[40])∥(˜Ci[39] && ˜Cn[39] && Sn[40])

The term (˜C[31] && C[31] && Sn[40]) can be canceled, and (˜Ci[39] && ˜Cn[39] && Sn[40]) can be removed because if both Ci[39] and Cn[39] are zero, one of the other expressions will select Sn[40]

S[40]=(C[31] && Ci[39] && Si[40])∥(˜C[31] && Cn[39] && Si[40])∥(˜C[31] && ˜Cn[39] && Sn[40])∥(C[31] && ˜Ci[39] && Sn[40])

The C[31] terms are reverse distributed so that C[31] (e.g., from the 32-bit tree adder 704) can be used to select the output:

S[40]=C[31] && (Ci[39] && Si[40]∥˜Ci[39] && Sn[40])∥˜C[31] && (Cn[39] && Si[40]∥˜Cn[39] && Sn[40])

Sif[40] represents the final incremented sum, and Snf[40] represents the final non-incremented sum, which can be substituted in the foregoing expression to provide:

S[40]=C[31] && Sif[40]∥˜C[31] && Snf[40]

Accordingly, the final expression for S[40] uses C[31] to select the final sum (e.g., either incremented or non-incremented), which is implemented by the second level mux 728. Sif[40] and Snf[40] are provided by the first level mux 726, where Sif[40] is selected responsive to Ci[39] and Snf[40] is selected responsive to Cn[39]. A similar approach is useful to select the final sum for bit 41 as well. For example, Si [41], Sn[41], Ci[39], and Cn[39] are used to compute Sif[41] and Snf[41], which can then be selected responsive to C[31].

Although the circuit 700 of FIG. 7 is for a 42-bit adder width (e.g., 32+8+2), the examples described herein can be recursively applied to other adder widths, such as a 170-bit (e.g., 128+32+8+2) adder in which a tree adder is used to determine the 128 LSBs, and successively smaller carry select adders are used to determine the next 32, 8, and 2 MSBs. In this example, the 2-bit carry select adder would include first, second, and third levels of muxes (selected by C[167], C[159], and C[127], respectively. The 8-bit carry select adder would include first and second levels of muxes (selected by C[159] and C[127], respectively), and the 32-bit carry select adder includes a single mux selected by C[127]. In an example, the tree adder has a width of 2ⁿ bits and the successively smaller carry select adders have widths of, at most 2^{n-2m} bits, where m is the number of preceding (e.g., larger in width, lower in significant bits) adder stages. In the example of FIG. 7, the first adder circuit 702 is 32 bits wide (e.g., n=5), and thus the second adder circuit 712 is at most 8 bits wide (e.g., 2⁽⁵⁻²⁾) and the third adder circuit 722 is at most 2 bits wide (e.g., 2⁽⁵⁻⁴⁾). In these examples, sizing the adder circuits in this manner allows each carry select adder to provide its incremented and non-incremented outputs to the first level mux at least by the time that the preceding adder circuit provides its MSB carry out value, which enables the adder circuits described herein, in which input widths cross a power of two boundary, to provide a final sum in the time that it takes the LSB tree adder to provide its final sum. The adder circuits described herein thus do not incur an additional delay (beyond the LSB tree adder), despite A and B crossing a power of two boundary.

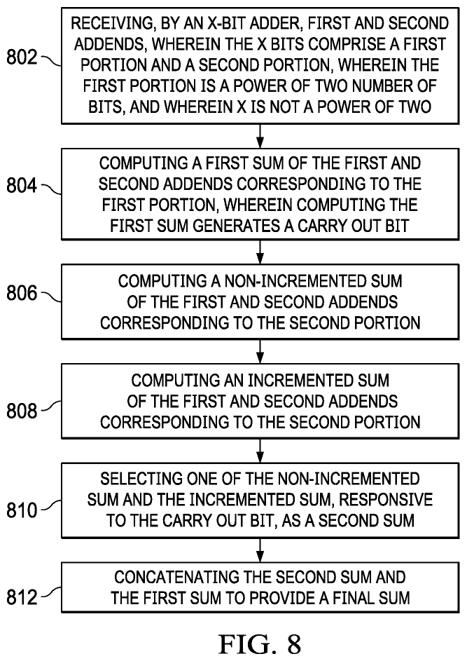

FIG. 8 is a flow chart of a method 800 in accordance with examples of this description. The method 800 begins in block 802 with receiving, by an x-bit adder, first and second addends (e.g., A and B). As described above, the addends cross a power of two boundary and thus x=2ⁿ+y, where x is not a power of two, the least-significant 2ⁿ bits are considered the first portion, and the most-significant y bits are considered the second portion.

The method 800 continues in block 804 with computing a first sum of the first and second addends corresponding to the first portion. As described above, first adder circuit 102 of FIG. 1, or first adder circuit 702 of FIG. 7 are configured to provide an output that is a sum of the bits of A and B corresponding to the first portion (e.g., the least-significant 2n bits of the addends A and B). The first adder circuit 102, 702 provides a carry out bit from its MSB position.

The method 800 continues further in block 806, with computing a non-incremented sum of the first and second addends corresponding to the second portion, and in block 808 with computing an incremented sum of the first and second addends corresponding to the second portion. As described above, the second adder circuit 104 of FIG. 1, or the second, third adder circuits 712, 722 of FIG. 7, are implemented as carry select adders, and are configured to provide as outputs incremented and non-incremented sums of the addends A and B corresponding to the second portion (e.g., the upper y bits of the addends A and B). In some cases, the non-incremented sum and the incremented sum are computed in blocks 806, 808 before or concurrently with computing the first sum in block 804.

Accordingly, the method 800 continues in block 810 with selecting one of the non-incremented sum and the incremented sum, responsive to the carry out bit, as a second sum. For example, the carry out from the first adder circuit 102 is provide as a select signal to the mux 114, and thus selects one of the incremented sum or the non-incremented sum provided by the second adder circuit 104. As described above, the output of the mux 114 is provided at approximately the same time as the sum logic 106 provides the first sum of the first and second addends corresponding to the first portion, and thus block 810 can also occur concurrently with computing the first sum in block 804.

The method 800 continues in block 812 with concatenating the second sum and the first sum to provide a final sum.

Referring again to the 10-bit addition example, in which y=2, the second adder circuit 104 thus includes one level of PG logic 210, 502; one level of group PG logic 212, 504; and one level of sum logic 112 prior to the mux 114. In this example, the first adder circuit 102 includes one level of PG logic 210 and three levels of group PG logic 212 before the carry out is provided (e.g., from bit position 7 in the last level of group PG logic 212). Accordingly, the inputs are available to the mux 114 at least by the time that the first adder logic 106 provides the carry out, and thus the second adder circuit 104 provides its output at approximately the same time as the first sum logic 108 provides the output of the first adder circuit 102. The method 800 thus provides the final sum without incurring an additional delay despite A and B crossing a power of two boundary.

The term “couple” is used throughout the specification. The term may cover connections, communications, or signal paths that enable a functional relationship consistent with this description. For example, if device A generates a signal to control device B to perform an action, in a first example device A is coupled to device B, or in a second example device A is coupled to device B through intervening component C if intervening component C does not substantially alter the functional relationship between device A and device B such that device B is controlled by device A via the control signal generated by device A.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While certain components may be described herein as being of a particular process technology, these components may be exchanged for components of other process technologies. Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

Uses of the phrase “ground voltage potential” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/−10 percent of the stated value. Modifications are possible in the described examples, and other examples are possible within the scope of the claims.

What is claimed is:

1. A method, comprising:
receiving, by an x-bit adder, first and second addends, wherein the x bits comprise a first portion and a second portion, wherein the first portion is a power of two number of bits, and wherein x is not a power of two;
computing a first sum of the first and second addends corresponding to the first portion, wherein computing the first sum generates a carry out bit;
computing a non-incremented sum of the first and second addends corresponding to the second portion;
computing an incremented sum of the first and second addends corresponding to the second portion;
selecting one of the non-incremented sum and the incremented sum, responsive to the carry out bit, as a second sum; and
concatenating the second sum and the first sum to provide a final sum.

2. The method of claim 1, wherein computing the first sum comprises determining first carry bits using a first group propagate-generate (PG) circuit, wherein computing the non-incremented sum comprises determining second carry bits using a second group PG circuit, wherein computing the incremented sum comprises determining third carry bits using a third group PG circuit, and wherein the second and third group PG circuits do not depend on the first group PG circuit.

3. The method of claim 2, wherein the third group PG circuit depends on the second group PG circuit.

4. The method of claim 1, wherein computing the first sum comprises determining first carry bits using a first tree adder, wherein computing the non-incremented sum comprises determining second carry bits using a second tree adder, and wherein an architecture of the first tree adder is different than an architecture of the second tree adder.

5. The method of claim 1, wherein computing the first sum comprises determining first carry bits using a first tree adder, wherein computing the non-incremented sum comprises determining second carry bits using a second tree adder, and wherein an architecture of the first tree adder is the same as an architecture of the second tree adder.

6. The method of claim 1, wherein x=10 and the second portion includes two bits.

7. The method of claim 1, wherein the first portion includes 2ⁿ bits and the second portion includes at most 2ⁿ⁻² bits.

8. A device, comprising:
a first adder circuit configured to compute a first sum of a first portion of first and second addends and generate a carry out bit associated with the first sum, wherein the first portion is a power of two number of bits; and
a second adder circuit configured to:
compute a non-incremented sum of a second portion of the first and second addends;
compute an incremented sum of the second portion of the first and second addends; and
select one of the non-incremented sum and the incremented sum, responsive to the carry out bit, as a second sum;
wherein a final sum of the device comprises the second sum concatenated with the first sum, and
wherein the final sum is not a power of two number of bits.

9. The device of claim 8, wherein the first adder circuit includes a first group propagate-generate (PG) circuit configured to determine first carry bits for the first portion of the first and second addends, wherein the second adder circuit includes a second group PG circuit configured to determine second carry bits for the non-incremented sum, wherein the second adder circuit includes a third group PG circuit configured to determine third carry bits for the incremented sum, and wherein the second and third group PG circuits do not depend on the first group PG circuit.

10. The device of claim 9, wherein the third group PG circuit depends on the second group PG circuit.

11. The device of claim 8, wherein the first adder circuit includes a first tree adder configured to determine first carry bits for the first portion of the first and second addends, wherein the second adder circuit includes a second tree adder configured to determine second carry bits for the second portion of the first and second addends, and wherein an architecture of the first tree adder is different than an architecture of the second tree adder.

12. The device of claim 8, wherein the first adder circuit includes a first tree adder configured to determine first carry bits for the first portion of the first and second addends, wherein the second adder circuit includes a second tree adder configured to determine second carry bits for the second portion of the first and second addends, and wherein an architecture of the first tree adder is the same as an architecture of the second tree adder.

13. The device of claim 8, wherein the first portion includes eight bits and the second portion includes two bits.

14. The device of claim 8, wherein the first portion includes 2ⁿ bits and the second portion includes at most 2ⁿ⁻² bits.

15. A device, comprising:
a first adder circuit configured to compute a first sum of a first portion of first and second addends and provide a first carry out bit associated with the first sum, wherein the first portion is a power of two number of bits;
a second adder circuit configured to:
compute a first non-incremented sum of a second portion of the first and second addends;
provide a non-incremented carry out bit associated with the first non-incremented sum;
compute a first incremented sum of the second portion of the first and second addends;
provide an incremented carry out bit associated with the first incremented sum; and
select one of the first non-incremented sum and the first incremented sum, responsive to the first carry out bit, as a second sum; and
a third adder circuit configured to:
compute a second non-incremented sum of a third portion of the first and second addends;
compute a second incremented sum of the third portion of the first and second addends; and
select one of the second non-incremented sum and the second incremented sum, responsive to the non-incremented carry out bit, the incremented carry out bit, and the first carry out bit, as a third sum;
wherein a final sum of the device comprises the third sum concatenated with the second sum, concatenated with the first sum, and
wherein the final sum is not a power of two number of bits.

16. The device of claim 15, wherein the first adder circuit includes a first group propagate-generate (PG) circuit configured to determine first carry bits for the first portion of the first and second addends, wherein the second adder circuit includes a second group PG circuit configured to determine second carry bits for the first non-incremented sum, wherein the second adder circuit includes a third group PG circuit configured to determine third carry bits for the first incremented sum, and wherein the second and third group PG circuits do not depend on the first group PG circuit.

17. The device of claim 16, wherein the third group PG circuit depends on the second group PG circuit.

18. The device of claim 15, wherein the third adder circuit is further configured to:
select one of the second non-incremented sum and the second incremented sum as a first intermediate sum responsive to the non-incremented carry out bit;
select one of the second non-incremented sum and the second incremented sum as a second intermediate sum responsive to the incremented carry out bit; and
select one of the first and second intermediate sums as the third sum responsive to the first carry out bit.

19. The device of claim 15, wherein the first portion includes 2ⁿ bits, the second portion includes at most 2^{n'2} bits, and the third portion includes at most 2ⁿ⁻⁴ bits.

20. The device of claim 15, wherein the first portion is less significant than the second portion, which is less significant than the third portion.
